(19) United States
(12) Patent Application Publication
(10) Pub. No.: US 2013/0064394 A1
(43) Pub. Date: Mar. 14, 2013

(54) DIGITAL SIGNAL GENERATOR AND DIGITAL MICROPHONE

(71) Applicant: Teruo IMAYAMA, Yokohama-shi (JP)

(72) Inventor: Teruo IMAYAMA, Yokohama-shi (JP)

(73) Assignee: Kabushiki Kaisha Toshiba, Tokyo (JP)

(21) Appl. No.: 13/398,103

(22) Filed: Feb. 16, 2012

(30) Foreign Application Priority Data
Sep. 8, 2011 (JP) 2011-196165

(51) Int. Cl. H03G 3/00; H03F 99/00; H03M 1/06

(52) U.S. Cl. 381/107; 341/119; 381/120

(57) ABSTRACT

According to one embodiment, a digital signal generator includes an amplifying unit, a reference voltage generator and a modulator. The amplifying unit amplifies an analog input signal having a signal level linearly depending on a temperature. The reference voltage generator generates a reference voltage linearly depending on the temperature. The modulator converts the analog input signal amplified by the amplifying unit into a digital output signal based on the reference voltage.

### CROSS REFERENCE TO RELATED APPLICATION(S)

This application is based upon and claims the benefit of priority from the prior Japanese Patent Application No. 2011-196165, filed on Sep. 8, 2011, the entire contents of which are incorporated herein by reference.

### FIELD

Embodiments described herein relate generally to a digital signal generator and a digital microphone.

### BACKGROUND

A conventional digital microphone includes a microphone component that outputs an electric signal, an amplifying unit that amplifies the electric signal according to a temperature, and an analog-digital conversion unit that converts an output of the amplifying unit into a digital signal.

The amplifying unit includes a resistance that has a linear characteristic, a MOS (Metal Oxide Semiconductor) switch that has a nonlinear characteristic, and a controller that controls turn-on and turn-off of the MOS switch according to the temperature. The controller controls the turn-on and the turn-off of the MOS switch according to the temperature, whereby a gain of the amplifying unit changes depending on the temperature. Therefore, the electric signal is amplified depending on the temperature.

However, because the MOS switch that has a nonlinear characteristic and the controller that controls the MOS switch are provided in the amplifying unit, a distortion and a variation of the gain are increased. That is, in the conventional digital microphone, the distortion and the variation of the gain are increased when what the signal changes depending on the temperature is cancelled.

### BRIEF DESCRIPTION OF THE DRAWINGS

FIG. 1 is a block diagram illustrating the configuration of the digital microphone 1 of the embodiment.

FIG. 2 is a block diagram illustrating the configuration of the amplifying unit 12 of the embodiment.

FIG. 3 is a block diagram illustrating the configuration of the ADC 14 of the embodiment.

FIG. 4 is a graph illustrating a relationship between a reference voltage Vref and a gain G of the analog output signal Aout of the embodiment.

FIG. 5 is a block diagram illustrating the configurations of the reference voltage generator 142 and the reference voltage adjuster 144 of the embodiment.

FIG. 6 is a graph illustrating characteristics of a first voltage V1 to a third voltage V3 and the reference voltage Vref of the embodiment.

FIG. 7 illustrates a data structure of a parameter table of the embodiment.

### DETAILED DESCRIPTION

Embodiments will now be explained with reference to the accompanying drawings.

In general, according to one embodiment, a digital signal generator includes an amplifying unit, a reference voltage generator and a modulator. The amplifying unit amplifies an analog input signal having a signal level linearly depending on a temperature. The reference voltage generator generates a reference voltage linearly depending on the temperature. The modulator converts the analog input signal amplified by the amplifying unit into a digital output signal based on the reference voltage.

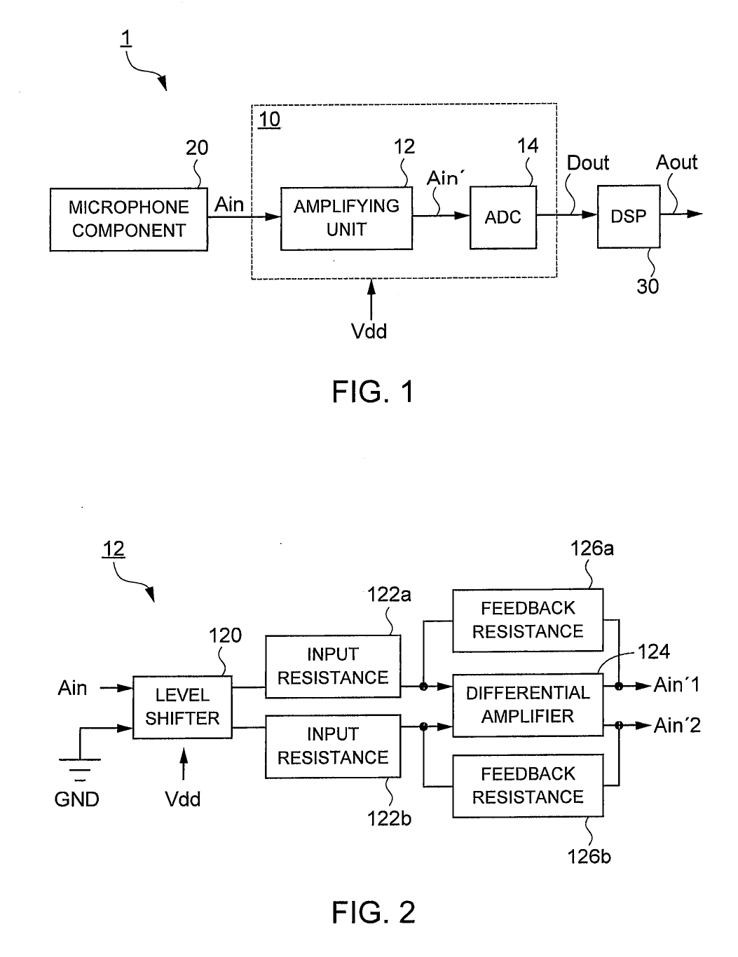

A configuration of a digital microphone 1 according to an embodiment will be described below. FIG. 1 is a block diagram illustrating the configuration of the digital microphone 1 of the embodiment.

Referring to FIG. 1, the digital microphone 1 includes a digital signal generator 10, a microphone component 20, and a DSP (Digital Signal Processor) 30.

The microphone component 20 is an electrostatic microphone component. The microphone component 20 generates an analog input signal Ain that is the electric signal based on change of a capacitance corresponding to an input sound pressure. The analog input signal Ain linearly depends on a temperature T in the digital microphone 1. A signal level of the analog input signal Ain is increased with increasing temperature T.

The digital signal generator 10 includes an amplifying unit 12 and an ADC (Analog Digital Converter) 14. The amplifying unit 12 and the ADC 14 are operated based on a power supply voltage Vdd. The amplifying unit 12 amplifies the analog input signal Ain at an amplification factor independent of the temperature T, and generates an amplified signal Ain′. The ADC 14 converts the amplified signal Ain′ into a digital output signal Dout.

The DSP 30 performs predetermined digital processing on the digital output signal Dout, and generates an analog output signal Aout. For example, the DSP 30 includes a low-pass filter or a Fourier converter.

A configuration of the amplifying unit 12 of the embodiment will be described below. FIG. 2 is a block diagram illustrating the configuration of the amplifying unit 12 of the embodiment.

Referring to FIG. 2, the amplifying unit 12 includes a level shifter 120, input resistances 122a and 122b, a differential amplifier 124, and feedback resistances 126a and 126b.

The level shifter 120 shifts a bias potential of the analog input signal Ain from a ground potential at a ground GND to a substantially half potential of the power supply voltage Vdd. Specifically, the level shifter 120 includes two input terminals (a first input terminal and a second input terminal) and two output terminals (a first output terminal and a second output terminal). The first input terminal of the level shifter 120 is connected to an output terminal of the microphone component 20 of FIG. 1, and inputs the analog input signal Ain. The second input terminal of the level shifter 120 is connected to the ground GND. That is, a potential at the second input terminal of the level shifter 120 is the ground potential. As a result, the first input terminal of the level shifter 120 is biased to the ground potential by a resistance component which is extremely high.

The input resistances 122a and 122b are connected to the first output terminal and the second output terminal of the level shifter 120, respectively. Furthermore, the input resistances 122a and 122b are also connected to a first output terminal and a second output terminal of the differential amplifier 124, respectively. Resistance values of the input resistances 122a and 122b have linearity to the temperature T.

The differential amplifier 124 includes a conversion function of performing single-differential conversion of an output signal (that is, the analog input signal Ain having the bias potential shifted to the substantially half potential of the power supply voltage) of the level shifter 120 and an amplification function of amplifying the output signal of the level shifter 120. Specifically, the differential amplifier 124 includes the two input terminals (a first input terminal and a second input terminal) and two output terminals (a first output terminal and a second output terminal).

The first input terminal and the second input terminal of the differential amplifier 124 are connected to the input resistances 122a and 122b, respectively. Furthermore, the first input terminal and the second input terminal of the differential amplifier 124 are also connected to the feedback resistances 126a and 126b, respectively.

The first output terminal and the second output terminal of the differential amplifier 124 are connected to the feedback resistances 126a and 126b, respectively. Furthermore, the first output terminal and the second output terminal of the differential amplifier 124 are also connected to the ADC 14 of FIG. 1.

The differential amplifier 124 outputs two output signals Ain′1 and Aln′2 according to a difference between the two input signals, which are supplied to the first input terminal and the second input terminal of the differential amplifier 124, respectively. The differential amplifier 124 may further include a limiter function of reducing a signal level of the output signal of the level shifter 120 such that the signal level of the output signal of the level shifter 120 becomes a predetermined threshold or less when the output signal of the level shifter 120 exceeds the threshold.

The feedback resistance 126a and 126b are connected to the first input terminal and the second input terminal the differential amplifier 124, respectively. Furthermore, the feedback resistances 126a and 126b are also connected to the first output terminal and the second output terminal of the differential amplifier 124, respectively. The feedback resistances 126a and 126b feed back the output signals Ain′1 and Ain′2 of the differential amplifier 124 to the differential amplifier 124, respectively. Resistance values of the feedback resistances 126a and 126b have linearity to the temperature T.

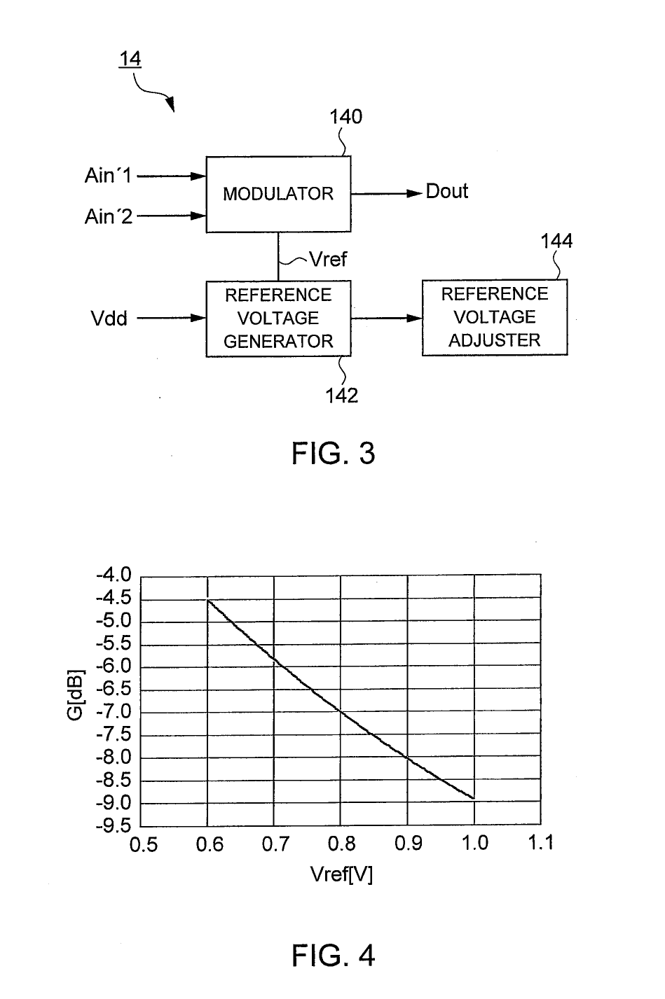

A configuration of the ADC 14 of the embodiment will be described below. FIG. 3 is a block diagram illustrating the configuration of the ADC 14 of the embodiment. FIG. 4 is a graph illustrating a relationship between a reference voltage Vref and a gain G of the analog output signal Aout of the embodiment.

Referring to FIG. 3, the ADC 14 includes a modulator 140, a reference voltage generator 142, and a reference voltage adjuster 144.

The modulator 140 converts the output signals Ain′1 and Ain′2 of the differential amplifier 124 into the digital output signal Dout using a full-scale voltage that is N-times (for example, N=4) the reference voltage Vref generated by the reference voltage generator 142. For example, the modulator 140 is a fourth-order discrete delta-sigma modulator, and the digital output signal Dout is a PCM (Pulse Code Modulation) signal.

At this point, the analog output signal Aout is expressed by an equation 1 using the signal level Vin′ of the output signals Ain′1 and Ain′2 of the differential amplifier 124. From the equation 1, the analog output signal Aout is decreased by about −0.8 dB when the full-scale voltage becomes 1.1 times. That is, from the equation 1, when the reference voltage Vref is increased, the gain (that is, the gain of the digital microphone 1) G of the analog output signal Aout to the analog input signal Ain is linearly decreased (see FIG. 4).

$$Aout = 20 \times log ( \frac{{Vin}^{′}}{4 \times Vref} ) [ dBFS ] \qquad ( equation 1 )$$

The reference voltage generator 142 generates the reference voltage Vref such that the characteristic of FIG. 4 is satisfied. That is, the reference voltage generator 142 defines the full-scale voltage of the modulator 140. The reference voltage adjuster 144 controls the reference voltage generator 142 such that the reference voltage Vref is adjusted according to the temperature T.

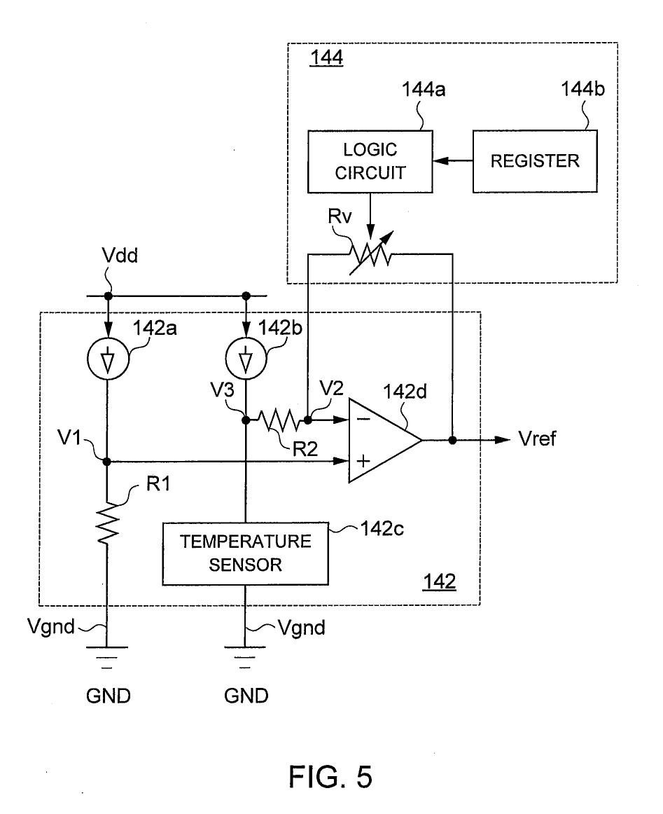

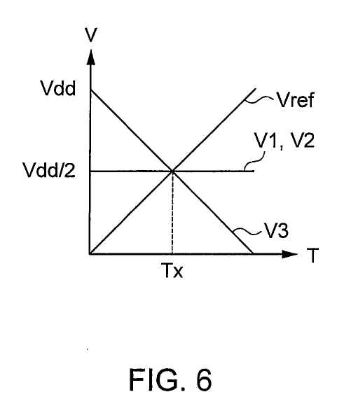

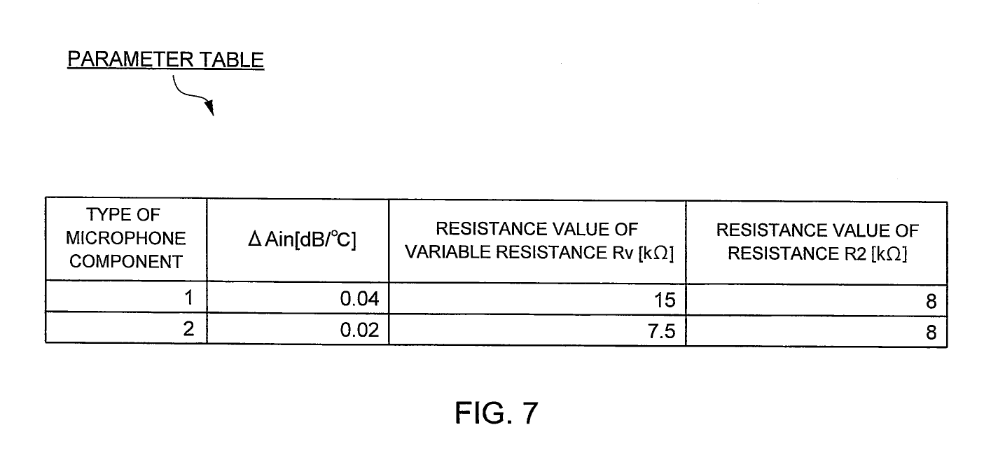

Configurations of the reference voltage generator 142 and the reference voltage adjuster 144 of the embodiment will be described below. FIG. 5 is a block diagram illustrating the configurations of the reference voltage generator 142 and the reference voltage adjuster 144 of the embodiment. FIG. 6 is a graph illustrating characteristics of a first voltage V1 to a third voltage V3 and the reference voltage Vref of the embodiment. FIG. 7 illustrates a data structure of a parameter table of the embodiment.

Referring to FIG. 5, the reference voltage generator 142 includes constant current sources 142a and 142b, a temperature sensor 142c, and a reference voltage generation source 142d. The reference voltage adjuster 144 that adjusts a temperature change ΔVref of the reference voltage Vref includes a logic circuit 144a and a register (storing unit) 144b.

The constant current sources 142a and 142b generate constant currents irrespective of the power supply voltage Vdd. The first voltage V1 is applied to a positive terminal of the reference voltage generation source 142d according to the constant current generated by the constant current source 142a and a resistance value of a resistance R1. As illustrated in FIG. 6, for example, the first voltage V1 is fixed to Vdd/2 irrespective of the temperature T. On the other hand, the second voltage V2 is applied to a negative terminal of the reference voltage generation source 142d according to the constant current generated by the constant current source 142b, the third voltage V3 (that is, the voltage corresponding to the temperature T) of the output signal of the temperature sensor 142c, and a resistance value of a resistance R2. As illustrated in FIG. 6, the third voltage V3 is linearly decreased with increasing temperature T. The temperature sensor 142c that is located at an arbitrary position in the digital microphone 1 generates a current corresponding to the temperature T. For example, the temperature sensor 142c is a thermosensitive diode.

A variable resistance Rv includes plural resistances and plural switches that switch between turn-ons and turn-offs of the resistances. Resistance values of the resistances may be equal to each other, or different from each other. A parameter table is stored in the register 144b. A parameter table of FIG. 7 indicates a relationship among a temperature change ΔAin [dB/° C.] of the analog input signal Ain, the resistance value [kΩ] of the variable resistance Rv, and the resistance value [kΩ] of the resistance R2. The temperature change ΔAin of the analog input signal Ain is defined by a type of the microphone component. The logic circuit 144a switches between the turn-ons and the turn-offs of the switches in the variable resistance Rv based on the parameter table stored in the register 144b. Therefore, a combination of the resistance value [kΩ] of the variable resistance Rv and the resistance value [kΩ] of the resistance R2 can be changed according to the temperature change ΔAin (that is, the type of the microphone component) of the analog input signal Ain. The parameter table is rewritable.

The reference voltage generation source 142d generates the reference voltage Vref according to the first voltage V1, the second voltage V2, and the resistance value of the variable resistance Rv. As illustrated in FIG. 6, the reference voltage Vref is linearly increased with increasing temperature T. That is, the reference voltage generation source 142d generates the reference voltage Vref according to the temperature T. The first voltage V1 to the third voltage V3 and the reference voltage Vref become an equal value (Vdd/2) at a predetermined temperature Tx (for example, 25° C.).

A specific example of the embodiment will be described below.

For example, in the case that the temperature change ΔAin of the analog input signal Ain is +0.04 [dB/° C.], a temperature change ΔG of the gain G of the modulator 140 is −0.04 [dB/° C.] necessary to cancel the temperature change ΔAin of the analog input signal Ain. From a temperature change per degree Celsius ΔVref of the reference voltage Vref, a change ratio ΔAout of the analog output signal Aout (hereinafter referred to as an “analog output change ratio”), and the equation 1, an equation 2 holds. From the equation 2, the temperature change ΔVref of the reference voltage Vref is about 0.0046. That is, when the reference voltage Vref is changed by about 0.46% per degree Celsius, the temperature change ΔAin of the analog input signal Ain is cancelled.

$$Δ Aout = 20 \times log ( \frac{1}{1 + Δ Vref} ) = - 0.04 [ dBFS ] \qquad ( equation 2 )$$

The digital signal generator 10 of the embodiment includes the amplifying unit 12 that amplifies the analog input signal Ain having the signal level linearly depending on the temperature T, the reference voltage generator 142 that generates the reference voltage Vref linearly depending on the temperature T, and the modulator 140 that converts the analog input signal (amplified signal Ain′), which is amplified by the amplifying unit 12, into the digital output signal Dout based on the reference voltage Vref. Particularly, the reference voltage generator 142 includes the temperature sensor 142c that detects the temperature T and the reference voltage generation source 142d that generates the reference voltage Vref according to the output of the temperature sensor 142c. According to the embodiment, the reference voltage Vref that defines the full-scale voltage of the modulator 140 is controlled according to the temperature T. As a result, the distortion and the variation of the gain can be reduced when the temperature change ΔAin of the analog input signal Ain is cancelled.

Moreover, the digital signal generator 10 of the embodiment further includes the reference voltage adjuster 144 that adjusts the gain of the reference voltage generator 142 based on the temperature T. Particularly, the reference voltage adjuster 144 includes the variable resistance Rv, the register 144b in which the parameter table is stored, and the logic circuit 144a that controls the resistance value of the variable resistance Rv based on the parameter table. The parameter table indicates the relationship among the temperature change ΔAin of the analog input signal Ain, the resistance value of the variable resistance Rv, and the resistance value of the resistance R2. According to the embodiment, the temperature change ΔVref of the reference voltage Vref can be adjusted. Particularly, the temperature change ΔVref of the reference voltage Vref can be adjusted according to the temperature change ΔAin of the analog input signal by rewriting the parameter table according to the type of the microphone component. Therefore, the digital signal generator 10 can easily applied to various microphone components 20 and various DSPs 30 without changing the circuit configuration of the digital signal generator 10.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A digital signal generator comprising:
an amplifying unit configured to amplify an analog input signal having a signal level linearly depending on a temperature;
a reference voltage generator configured to generate a reference voltage linearly depending on the temperature; and
a modulator configured to convert the analog input signal amplified by the amplifying unit into a digital output signal based on the reference voltage.

2. The generator of claim 1, wherein the reference voltage generator further comprises:
a temperature sensor configured to detect the temperature and generate a current corresponding to the detected temperature; and
a reference voltage generation source configured to generate the reference voltage corresponding to the current generated by the temperature sensor.

3. The generator of claim 1, further comprising, a reference voltage adjuster configured to adjust gain of the reference voltage generator based on the temperature.

4. The generator of claim 2, further comprising a reference voltage adjuster configured to adjust gain of the reference voltage generator based on the temperature.

5. The generator of claim 3, wherein the reference voltage adjuster comprises:
a variable resistance;
a storing unit configured to store a parameter table indicating relationship between a resistance value of the variable resistance and the temperature; and
a logic circuit configured to control the resistance value of the variable resistance based on the parameter table.

6. The generator of claim 4, wherein the reference voltage adjuster comprises:
a variable resistance;
a storing unit configured to store a parameter table indicating relationship between a resistance value of the variable resistance and the temperature; and
a logic circuit configured to control the resistance value of the variable resistance based on the parameter table.

7. A digital microphone comprising:
a microphone component configured to generate an analog input signal having a signal level linearly depending on a temperature;
an amplifying unit configured to amplify the analog input signal;
a reference voltage generator configured to generate a reference voltage linearly depending on the temperature;
a modulator configured to convert the analog input signal amplified by the amplifying unit into a digital output signal based on the reference voltage; and
a digital signal processor configured to perform digital processing on the digital output signal.

8. The microphone of claim 7, wherein the reference voltage generator further comprises:
a temperature sensor configured to detect the temperature and generate a current corresponding to the detected temperature; and
a reference voltage generation source configured to generate the reference voltage corresponding to the current generated by the temperature sensor.

9. The microphone of claim 7, further comprising a reference voltage adjuster configured to adjust gain of the reference voltage generator based on the temperature.

10. The microphone of claim 8, further comprising a reference voltage adjuster configured to adjust gain of the reference voltage generator based on the temperature.

11. The microphone of claim 9, wherein the reference voltage adjuster comprises:
a variable resistance;
a storing unit configured to store a parameter table indicating relationship between a resistance value of the variable resistance and the temperature; and
a logic circuit configured to control the resistance value of the variable resistance based on the parameter table.

12. The microphone of claim 10, wherein the reference voltage adjuster comprises:
a variable resistance;
a storing unit configured to store a parameter table indicating relationship between a resistance value of the variable resistance and the temperature; and
a logic circuit configured to control the resistance value of the variable resistance based on the parameter table.
